(19) United States
(12) Patent Application Publication
(10) Pub. No.: US 2008/0308832 A1
(43) Pub. Date: Dec. 18, 2008

(54) Light-emitting device

(75) Inventors: Min-Hsun Hsieh, Hsinchu (TW); Chiu-Lin Yao, Hsinchu (TW)

Correspondence Address: BACON & THOMAS, PLLC, 625 SLATERS LANE, FOURTH FLOOR, ALEXANDRIA, VA, 22314-1176, US

(73) Assignee: EPISTAR CORPORATION, Hsinchu (TW)

(21) Appl. No.: 12/213,129

(22) Filed: Jun. 16, 2008

(30) Foreign Application Priority Data
Jun. 14, 2007 (TW) 96121676

(51) Int. Cl. H01L 33/00

(52) U.S. Cl. 257/98; 257/E33.067

(57) ABSTRACT

A light-emitting device comprises a semiconductor light-emitting stack; and an optical field tuning layer formed on the semiconductor light-emitting stack to change beam angles of the light-emitting device.

### REFERENCE TO RELATED APPLICATION

This application claims the right of priority based on TW application Ser. No. 96121676, filed Jun. 14, 2007, entitled “Light-Emitting Device”, and the contents of which are incorporated herein by reference.

### BACKGROUND OF THE DISCLOSURE

1. Technical Field

The present invention relates to a light-emitting device, and in particular to a semiconductor light-emitting device. 2. Description of the Related Art

The light-emitting mechanism and the structure of a light-emitting diode (LED) are different from that of the conventional light sources. The LED has the advantages of small size and high reliability, and has widely used in different fields such as displays, laser diodes, traffic lights, data storage apparatus, communication apparatus, lighting apparatus, and medical apparatus. Because of the successful development of high brightness LEDs, LED can be applied to indoor or large outdoor displays. Besides, LEDs can substitute the CCFL to be the light source of the backlight module in the advantages of high color saturation, a high color contrast, and an ultra slim structure. The optical-electrical characteristics of LEDs are adjustable to satisfy different requirements. For example, the light emitted from the LED comprises an optical field distribution which can be defined by a beam angle. The smaller beam angle the LED has, the higher directionality the LED appears. For the LEDs in the backlight module, the high directionality is not required, but the larger beam angle and the wider optical field distribution are. A specific optical field distribution can be produced by changing the LED structure. For example, an LED chip comprising an absorption substrate emits light from its top surface and forms a narrower optical field distribution and a smaller beam angle. By contrast, the light emitted from an LED chip with a transparent substrate can be extracted from the sidewalls of the transparent substrate easily, and therefore a wider optical field distribution and a larger beam angle are formed. An LED with the narrower optical field distribution and the smaller beam angle can be changed to a wider optical field distribution by redesigning the structure of the LED like growing a thicker window layer on the light emitting epitaxial layers to increase the light extraction from the sidewalls of the LED to form a wider optical field distribution.

The manufacturers design various kinds of LEDs to satisfy customers' requirements of optical field distribution. The different kinds of LED with the different kinds of process increase the complexity of production, decrease the production efficiency, and increase the cost.

### SUMMARY OF THE DISCLOSURE

Accordingly, the present invention is to provide a light-emitting device. The light-emitting device includes an optical field tuning layer on a light-emitting stack to change the far-field angle of the light-emitting device. As embodied and broadly described herein, the present invention provides a light-emitting device including a semiconductor light-emitting stack, an optical field tuning layer, and an electrode. The light-emitting stack includes at least one light extraction surface, and the optical field tuning layer is formed directly on the light extraction surface. The optical field tuning layer includes at least a first layer and a second layer. The first layer is closer to the semiconductor light-emitting stack than the second layer and the refraction index of the first layer is smaller than the refraction index of the second layer. The electrode is formed on the semiconductor light-emitting stack wherein the electrode is in contact with at least one of the light extraction surface and the optical field tuning layer.

### BRIEF DESCRIPTION OF THE DRAWINGS

The accompanying drawings are included to provide easy understanding of the invention, and are incorporated herein and constitute a part of this specification. The drawings illustrate embodiments of the invention and, together with the description, serve to illustrate the principles of the invention.

FIG. 1 is a schematic cross-sectional view of a light-emitting device in accordance with a first embodiment of the present invention.

FIGS. 2A-2D are diagrams showing optical field distributions of the conventional light-emitting device and light-emitting devices in accordance with the first embodiment of the present invention.

FIG. 3 is a schematic cross-sectional view of a light-emitting device in accordance with a second embodiment of the present invention.

FIGS. 4A-4E are diagrams showing optical field distributions of the conventional light-emitting device and light-emitting devices in accordance with the second embodiment of the present invention.

FIG. 5 is a schematic cross-sectional view of a light-emitting device in accordance with a third embodiment of the present invention.

FIGS. 6A-6E are diagrams showing optical field distributions of the conventional light-emitting device and light-emitting devices in accordance with the third embodiment of the present invention.

FIG. 7 is a schematic cross-sectional view of a light-emitting device in accordance with a fourth embodiment of the present invention.

FIGS. 8A-8D are diagrams showing optical field distributions of the conventional light-emitting device and light-emitting devices in accordance with the fourth embodiment of the present invention.

FIG. 9 is a schematic cross-sectional view of a light-emitting device in accordance with a fifth embodiment of the present invention.

FIGS. 10A-10D are diagrams showing optical field distributions of the conventional light-emitting device and light-emitting devices in accordance with the fifth embodiment of the present invention.

FIG. 11 is a schematic cross-sectional view of a light-emitting device in accordance with a sixth embodiment of the present invention.

FIG. 12 is a schematic cross-sectional view of a light source element including a light emitting device of the present invention.

FIG. 13 is a schematic cross-sectional view of a backlight module including a light emitting device of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

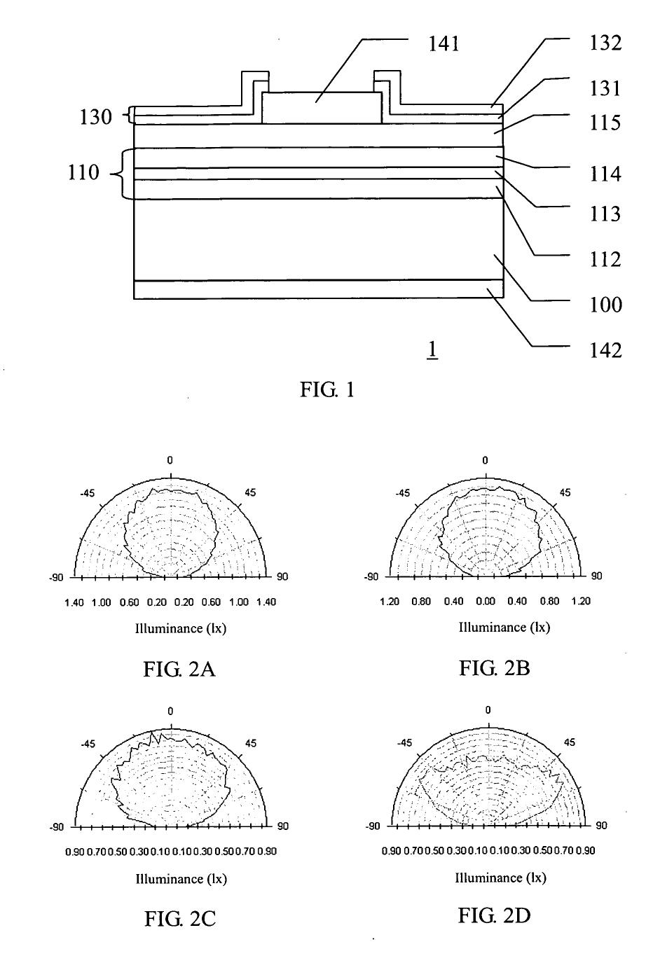

Referring to FIG. 1, the schematic cross-sectional view shows a light-emitting device 1 in accordance with a first embodiment of the present invention. The light-emitting device 1 such as an LED comprises a substrate 100, a semiconductor light-emitting stack 110, an optical field tuning layer 130, and upper and lower electrodes 141 and 142. The material of the substrate 100 includes III-V semiconductor material such as GaAsP, GaAs, or GaP. The semiconductor light-emitting stack 110 formed on the substrate 100 includes an n-type semiconductor layer 112, a p-type semiconductor layer 114, an active layer interposed therebetween, and a second p-type semiconductor layer 115. In some embodiments, the arrangements of the n-type and p-type semiconductor layers 112 and 114 can be interchanged, and the second p-type semiconductor layer 115 can be replaced by a second n-type semiconductor layer. In the embodiment, the n-type and p-type semiconductor layers 112 and 114 act as cladding layers of the LED and include III-V group compound semiconductor materials such as AlGaInP, AlGaAs, AlGaInN, or other ternary or quaternary III-V group compound semiconductor materials. The active layer 113 acts as a light-emitting layer including III-V group compound semiconductor materials such as AlGaInP, AlGaInN or other materials matched with the n-type and p-type semiconductor layers 112 and 114. The second p-type semiconductor layer 115 acts as a contact layer in contact with the electrode and includes III-V group compound semiconductor materials such as GaP or GaN. The upper and lower electrodes 141 and 142 are formed on the top of the semiconductor light-emitting stack 110 and the bottom of the substrate 100 respectively. After the upper electrode 141 is formed, the optical field tuning layer 130 is then formed on a predetermined position on the semiconductor light-emitting stack 110 by lithography process. In the embodiment, the optical field tuning layer 130 includes a first layer 131 and a second layer 132. The first layer is formed on the semiconductor light-emitting stack 110 and covers at least a portion of the upper electrode 141. The second layer 132 is formed on the first layer 131 and has a refraction index larger than that of the first layer 131. The light emitted from the semiconductor light-emitting stack 110 to the top surface of the light emitting device is reflected back to the semiconductor light-emitting stack 110 by the optical field tuning layer 130, and is extracted from the sidewalls of the semiconductor light-emitting stack 110. Therefore, the far-field angle of the light-emitting device 1 is greater than the far-field angle of the light-emitting device without the optical field tuning layer 130.

In some embodiments, the optical field tuning layer 130 is formed on the semiconductor light-emitting stack 110 and surrounds the upper electrode 141 conformably. The optical field tuning layer 130 also can be formed on at least a portion of the semiconductor light-emitting stack 110 and therefore expose a circular area surrounding the upper electrode 141.

In the embodiment, the optical field tuning layer 130 can be formed by chemical vapor deposition method (CVD), evaporation or sputtering, and its structure is not limited to only one set of the first layer 131 and the second layer 132, but can be formed repeatedly. Besides, either of the first layer 131 and the second layer 132 can be composed of the same materials with various proportion controlled by the process such that the refraction index of the optical field tuning layer 130 can be increased gradually from the first layer 131 to the second layer 132. The optical field distribution of a light-emitting device disclosed in the present invention can be tuned by varying the number of layers of the first layer 131 and the second layer 132 to change the far-field angle. In the embodiment, the material of the first layer 131 includes but is not limited to conductive metal oxide or insulating material. The upper electrode 141 can be formed on the first layer 131 when the material of the first layer 131 is conductive metal oxide. The insulating material of the first layer 131 includes but is not limited to SiO₂, SiNₓ, SiON, ZrO₂, Ta₂O₅, Al₂O₃, or TiO₂. The material of the second layer 132 includes but is not limited to conductive metal oxide or insulating material. The upper electrode 141 can be formed on the second layer 132 when the material of the second layer 132 is conductive metal oxide. The insulating material of the second layer 132 includes but is not limited to SiO₂, SiNₓ, SiON, ZrO₂, Ta₂O₅, Al₂O₃, or TiO₂. The conductive metal oxides of the first layer 131 and the second layer 132 include but are not limited to indium tin oxide, cadmium tin oxide, zinc oxide, or zinc tin oxide. The first layer 131 and the second layer 132 can also be a multilayer structure composed of different materials such as SiO₂/SiNₓ, SiO₂/TiO₂, SiON/SiNₓ, or metal oxide/SiNx.

In another embodiment, the surface of the semiconductor light-emitting stack 110 and/or the interface of the semiconductor light-emitting stack 110 and the substrate 100 can be optionally roughened to improve the light extraction efficiency. The roughened surface can be formed during the exitaxy process. They also can be formed by a randomly etching method or a lithographical etching to form a regular or an irregular patterned surface.

Normally the light is extracted from the top and sidewalls of a light-emitting device. In order to form an optical field distribution with a larger far-field angle, the light extraction from the top surface has to be decreased and the light extraction from side-wall surfaces has to be increased. Therefore, the optical field tuning layer 130 disposed on the light extraction surface can vary the optical field distribution and get a larger far-field angle. The optical field tuning layer 130 can be formed before or after forming the electrode. The number of layers of the first layer 131 and the second layer 132 can be adjusted based on the user's needs. Accordingly, without changing the structure of the substrate 100, the semiconductor light-emitting stack 110, and the upper and lower electrodes 141 and 142, the desired optical field distribution can be formed by just tuning the material composition, layer, or thickness of the first layer 131 and the second layer 132 as long as the refraction index of the first layer 131 is smaller than that of the second layer 132. The thickness of the first layer 131 and the second layer 132 is set by the electromagnetic theory:

$$d = \frac{1}{4 n} m \times {W}_{d}$$

wherein d is the thickness of the first layer 131 or the second layer 132, n is the refraction index of the first layer 131 or the second layer 132, m is the odd number greater than zero, and W_{d} is the wavelength of the light emitted from the semiconductor light-emitting stack.

In the embodiment, the material of the semiconductor light-emitting stack 110 is AlGaInP. The material of first layer 131 is SiO₂, and the refraction index n₁ is 1.6. The material of the second layer is SiNₓ, and the refraction index n₂ is 1.9. Each thickness of the first layer 131 and the second layer 132 based on the electromagnetic theory is 105 nm and 80 nm respectively. Referring to FIGS. 2A-2D, FIG. 2A illustrates the optical field distribution of a conventional light-emitting device without the optical field tuning layer 130, and FIGS. 2B-2D illustrate the optical field distributions of the light emitting device 1 of the present invention with one pair, three pairs, and five pairs of the optical field tuning layer 130 at 20 mA input current respectively. The optical field distribution is illustrated by a polar diagram illustrating the illuminance (1×) at different directions. At 50% illuminance (1×) of the optical field distribution, the beam angles of the conventional light-emitting device and the light emitting device 1 with one pair optical field tuning layer 130 are 126.3° and 132.8° respectively. When the number of the first layer 131 and the second layer 132 is three pairs, the beam angle of the light emitting device 1 is 144.3°. When the number of the first layer 131 and the second layer 132 is five pairs, the beam angle of the light emitting device 1 is 155.2°. So the optical field distribution of the light-emitting device can be varied by tuning the optical field tuning layer 130. The light-emitting device comprising more pairs of the first layer 131 and the second layer 132 has larger beam angle of the optical field distribution.

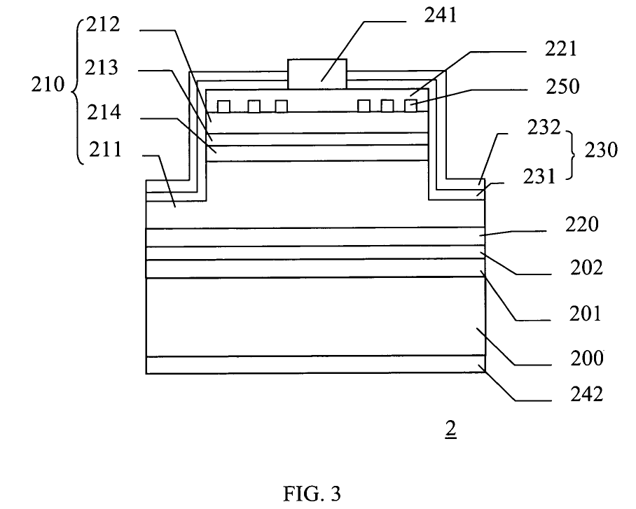

Referring to FIG. 3, the schematic cross-sectional view shows a light-emitting device 2 in accordance with a second embodiment of the present invention. The light-emitting device 2 includes a substrate 200, a conductive adhesive layer 201, a reflective layer 202, a first transparent conductive oxide layer 220, a semiconductor light-emitting stack 210, a distributed contact layer 250, a second transparent conductive oxide layer 221, an optical field tuning layer 230, and upper and lower electrodes 241 and 242. The material of the substrate 200 includes but is not limited to Si, GaAs, metal or other similar materials. The conductive adhesive layer 201 is formed on the substrate 200, and a first bonding interface is formed therebetween. The material of the conductive adhesive layer 201 includes but is not limited to Ag, Au, Al, In, spontaneous conductive polymer, or polymer doping with metal like Al, Au, Pt, Zn, Ag, Ni, Ge, In, Sn, Ti, Pb, Cu, Pd, or other metals. The reflective layer 202 is formed on the conductive adhesive layer 201, and a second bonding interface is formed therebetween. The material of the reflective layer 202 includes but is not limited to metal, oxide, or the combination thereof. The metal for the reflective layer 202 includes Al, Au, Pt, Zn, Ag, Ni, Ge, In, Sn or alloys of the abovementioned metals. The oxide material for the reflective layer 202 includes but is not limited to AlOₓ, SiOₓ, or SiNₓ. The first transparent conductive oxide layer 220 is formed on the reflective layer 202, and includes but is not limited to indium tin oxide, cadmium tin oxide, zinc oxide, or zinc tin oxide. The semiconductor light-emitting stack 210 is formed on the first transparent conductive oxide layer 220, including a thick semiconductor layer 211, a p-type semiconductor layer 214, an n-type semiconductor layer 212, and an active layer 213 interposed therebetween. In the embodiment, the semiconductor light-emitting stack 210 is etched partially from the n-type semiconductor layer 212, the active layer 213, and the p-type semiconductor layer 214 to the thick semiconductor layer 211 to expose a partial surface of the thick semiconductor layer 211. The materials of the n-type and p-type semiconductor layers 212 and 214 include III-V group compound semiconductor materials such as AlGaInP, AlGaAs, AlGaInN or other ternary or quaternary III-V group compound semiconductor materials. The active layer 213 includes III-V group compound semiconductor materials such as AlGaInP, AlGaInN or other materials matched with the n-type and p-type semiconductor layers 212 and 214. The thick semiconductor layers 211 acts as a light extraction layer for improving the light extraction efficiency and includes but is not limited to GaP, or GaN. The distributed contact layer 250 is formed on the semiconductor light-emitting stack 210 and includes but is not limited to metal, or semiconductor. The distributed pattern of the contact layer 250 includes line or point. The second transparent conductive oxide layer 221 is formed on the semiconductor light-emitting stack 210, and includes but is not limited to indium tin oxide, cadmium tin oxide, zinc oxide, or zinc tin oxide. The upper and lower electrodes 241 and 242 are formed on the top of semiconductor light-emitting stack 210 and the bottom of the substrate 200 respectively. The current is injected through the upper electrode 241 and moves to the second transparent conductive oxide layer 221, and then is spread through the distributed contact layer 250. The optical field tuning layer 230 is formed on the second transparent conductive oxide layer 221 and surrounds the upper electrode 241. The optical field tuning layer 230 includes a first layer 231 and a second layer 232 which covers the exposed surface of the thick semiconductor layer 211, and the sidewalls of the p-type semiconductor layer 214, the active layer 213, the n-type semiconductor layer 212, and the second transparent conductive oxide layer 221, and the top surface of the second transparent conductive oxide layer 221. The refraction index of the first layer 231 is smaller than that of the second layer 232. The structure of the optical field tuning layer 230 is not limited in one first layer 231 and one second layer 232; it can also be formed repeatedly depending on the optical field requirement. The material of the first layer 231 includes but is not limited to conductive metal oxide or insulating material. The insulating material of the first layer 231 includes but is not limited to SiO₂, SiNₓ, SiON, ZrO₂, Ta₂O₅, Al₂O₃, or TiO₂. The material of the second layer 232 includes but is not limited to conductive metal oxide or insulating material. The insulating material of the second layer 232 includes but is not limited to SiO₂, SiNₓ, SiON, ZrO₂, Ta₂O₅, Al₂O₃, or TiO₂. The conductive metal oxide of the first layer 231 and the second layer 232 includes but is not limited to indium tin oxide, cadmium tin oxide, zinc oxide, or zinc tin oxide. The materials of the first layer 231 and the second layer 232 can also be a multilayer structure composed of different materials such as SiO₂/SiNₓ, SiO₂/TiO₂, SiON/SiNₓ, or metal oxide/SiNx.

In another embodiment, a structure of a light-emitting device without the conductive adhesive layer 201 and the first transparent conductive oxide layer 220 can be formed by direct bonding method with high pressure to join the semiconductor light-emitting stack 210 and the substrate 200, or the reflective layer 202 and the substrate 200.

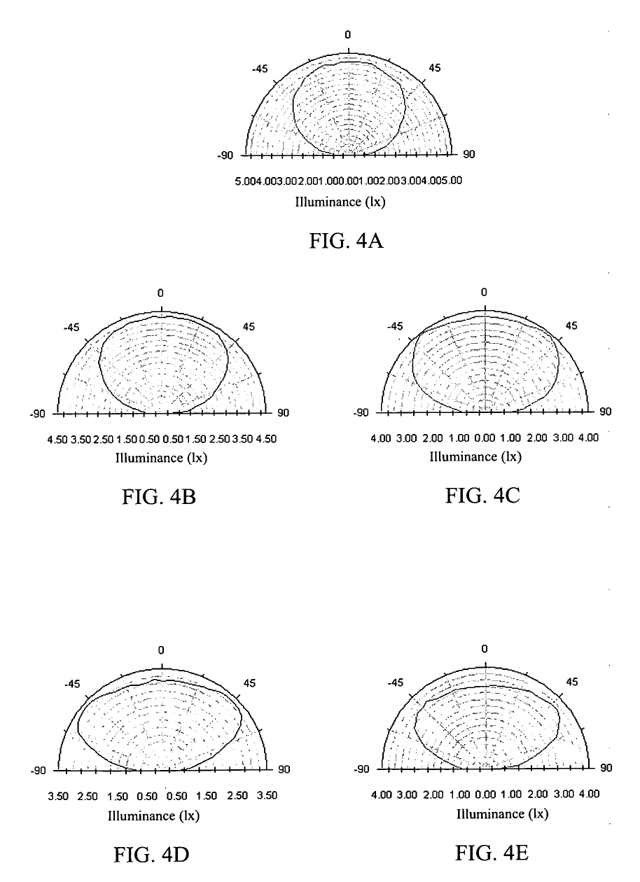

In the embodiment, the material of the semiconductor light-emitting stack 210 is AlGaInP. The material of the first layer 231 is SiO₂, the refraction index n₁ is 1.46, and the thickness is 105 nm. The material of the second layer 232 is SiNₓ, the refraction index n₂ is 1.9, and the thickness is 80 nm. Referring to FIGS. 4A-4E, FIG. 4A illustrates the optical field distribution of a conventional light-emitting device without the optical field tuning layer 230, and FIGS. 4B-4E illustrate the optical field distributions of the light emitting device 2 with one pair, three pairs, five pairs, and seven pairs of the optical field tuning layer 230 at 20 mA input current respectively. When the number of the first layer 231 and the second layer 232 is one pair, the light efficiency of the conventional light-emitting device is the same as the light emitting device 2. At 50% illuminance (1×) of the optical field distribution, the beam angles of the conventional light-emitting device and the light emitting device 2 are 138.4° and 141.5° respectively. When the number of the first layer 231 and the second layer 232 is three pairs, at 50% illuminance (1×) of the optical field distribution, the beam angle of the light emitting device 2 is 145.1°. When the number of the first layer 231 and the second layer 232 is five pairs, at 50% illuminance (1×) of the optical field distribution, the beam angle of the light emitting device 2 is 154.3°. When the number of the first layer 231 and the second layer 232 is seven pairs, at 50% illuminance (1×) of the optical field distribution, the beam angle of the light emitting device 2 is 155.0°. So the optical field distribution of the light-emitting device can be varied by tuning the optical field tuning layer 230. The more pairs of the first layer 231 and the second layer 232 the light-emitting device has, the larger beam angle of the optical field distribution is.

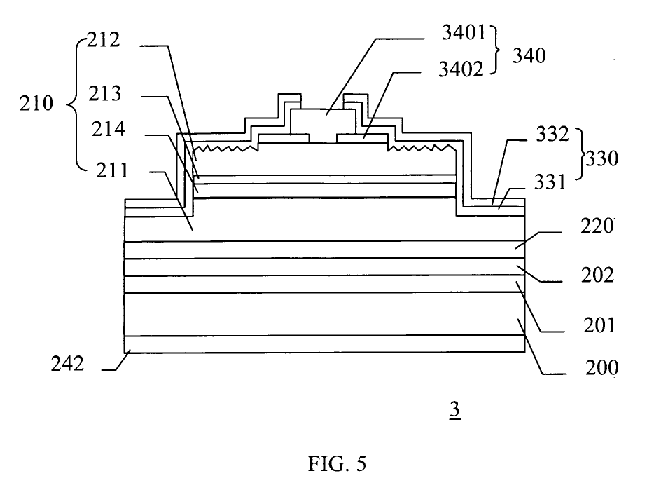

Referring to FIG. 5, the schematic cross-sectional view shows a light-emitting device 3 in accordance with a third embodiment of the present invention. The structure of the light-emitting device 3 is similar to the light emitting device 2, and the difference is the light emitting device 3 does not include the second transparent conductive oxide layer 221 and the distributed contact layer 250. The n-type semiconductor 212 of the light emitting device 3 includes a roughened top surface. The roughened top surface can be formed during the epitaxial process or by a randomly etching method to form a multi-cavity surface. It also can be formed by a lithographical etching to form a regular or an irregular patterned surface. The n-type semiconductor 212 also includes an even top surface, and an upper electrode 340 is formed on the even top surface. The even top surface can form an ohmic contact with the upper electrode 340. The upper electrode 340 includes a bonding electrode 3401 and an extension electrode 3402. After the current injects through the bonding electrode 3401, the current flows to and is spread through the extension electrode 3402. The optical field tuning layer 330 includes a first layer 331 and a second layer 332 which covers the exposed surface of the thick semiconductor layer 211, the sidewalls of the thick semiconductor layer 211, the p-type semiconductor layer 214, the active layer 213, and the n-type semiconductor layer 212, and the top surface of the n-type semiconductor layer 212 and the upper electrode 340. The material of the first layer 331 includes but is not limited to indium tin oxide, cadmium tin oxide, zinc oxide, zinc tin oxide, SiO₂, SiNₓ, SiON, ZrO₂, Ta₂O₅, Al₂O₃, or TiO₂. The material of the second layer 332 includes but is not limited to indium tin oxide, cadmium tin oxide, zinc oxide, zinc tin oxide, SiO₂, SiNₓ, SiON, ZrO₂, Ta₂O₅, Al₂O₃, or TiO₂.

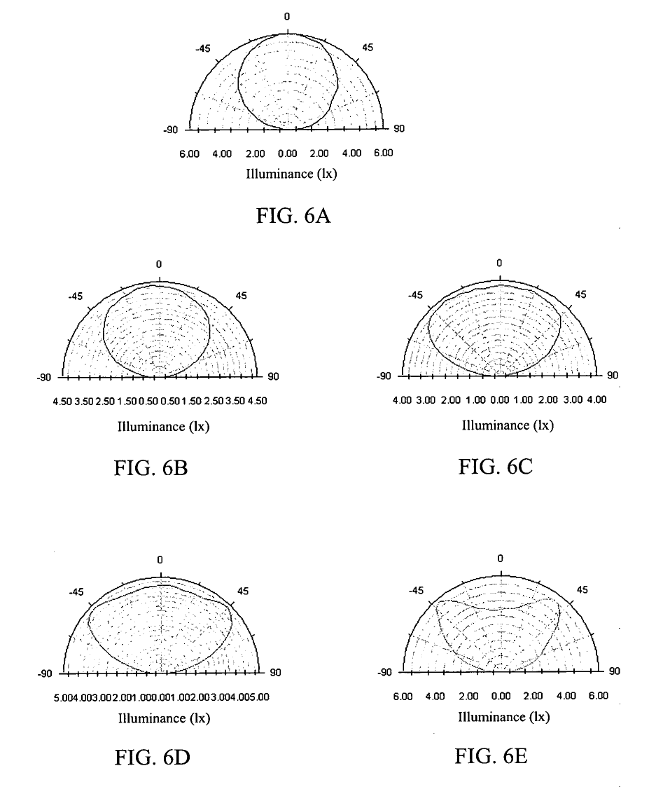

Referring to FIGS. 6A-6E, FIG. 6A illustrates the optical field distribution of a conventional light-emitting device without the optical field tuning layer 330. At 50% illuminance (1×) of the optical field distribution, the beam angle of the conventional light-emitting device is 120.2°. FIGS. 6B-6E illustrate the optical field distributions of the light emitting device 3 with two pairs, three pairs, four pairs, and six pairs of the first and second layers 331 and 332 respectively. At 50% illuminance (1×) of the optical field distribution, the beam angles of the light emitting device 3 with two, three, four, and six pairs are 129.8°, 142.9°, 143.7°, and 145.0° respectively. The optical field distribution of the light-emitting device 3 can be changed by tuning the optical field tuning layer 330. The more pairs of the first layer 331 and the second layer 332 the light-emitting device has, the larger beam angle of the optical field distribution is.

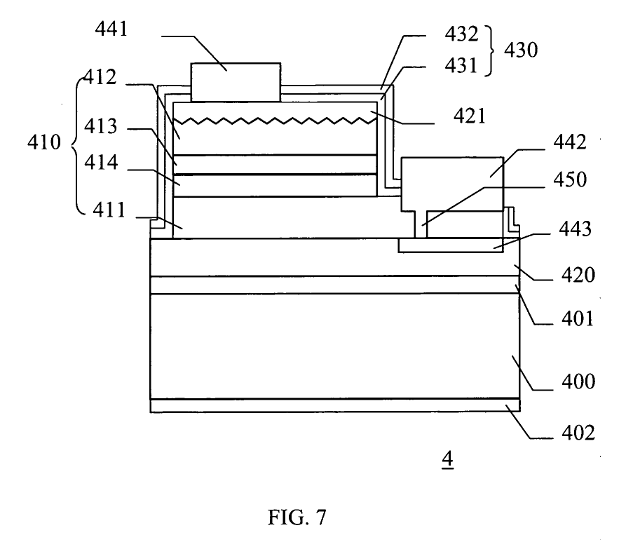

Referring to FIG. 7, the schematic cross-sectional view shows a light-emitting device 4 in accordance with a fourth embodiment of the present invention. The light-emitting device 4 includes a reflective layer 402, a transparent substrate 400, an insulating adhesive layer 401, a first transparent conductive oxide layer 420, an ohmic contact layer 443, a semiconductor light-emitting stack 410, a second transparent conductive oxide layer 421, an optical field tuning layer 430, and first and second electrodes 441 and 442. In the embodiment, the reflective layer 402 is formed on the lower surface of the transparent substrate 400. The material of the reflective layer 402 includes but is not limited to metal, oxide, or the combination of the metal and the oxide. The material of the metal includes but is not limited to Al, Au, Pt, Zn, Ag, Ni, Ge, In, Sn, or alloy of them. The metal includes but is not limited to Al, Au, Pt, Zn, Ag, Ni, Ge, In, Sn, or alloy of them. The oxide includes but is not limited to AlOₓ, SiOₓ, or SiNₓ. The material of the transparent substrate 400 includes but is not limited to glass, sapphire, SiC, GaP, GaAsP, or ZnSe. The insulating adhesive layer 401 is formed on the transparent substrate 400. The material of the insulating adhesive layer 401 includes but is not limited to spin on glass (SOG), silicone, polyimide (PI), benzocyclobutene (BCB), perfluorocyclobutane (PFCB), or epoxy. The first transparent conductive oxide layer 420 is formed on the insulating adhesive layer 401, and it includes but is not limited to indium tin oxide, cadmium tin oxide, zinc oxide, or zinc tin oxide. The semiconductor light-emitting stack 410 is formed on the first transparent conductive oxide layer 420, including a first p-type semiconductor layer 411, a second p-type semiconductor layer 414, an n-type semiconductor layer 412, and an active layer 413 interposed between the second p-type semiconductor layer 414 and the n-type semiconductor layer 412. The n-type and second p-type semiconductor layers 412 and 414 act as cladding layers of the LED. The n-type semiconductor 421 includes a roughened top surface. The roughened top surface can be formed during the epitaxial process or by a randomly etching method to form a multi-cavity surface. It also can be formed by a lithographical etching to form a regular or an irregular patterned surface. The ohmic contact layer 443 is formed between the first p-type semiconductor layer 411 and the first transparent conductive oxide layer 420, and it includes but is not limited to GeAu or BeAu. In the embodiment, the semiconductor light-emitting stack 410 is etched partially from the n-type semiconductor layer 412, the active layer 413, the second p-type semiconductor layer 414 to the first p-type semiconductor layer 411 to expose partial surface of the first p-type semiconductor layer 411. After etching, the first p-type semiconductor layer 411 is etched from the exposed surface to the ohmic contact layer 443 to form a tunnel 450. Besides, in order to improve the light extraction from the first p-type semiconductor layer 411 to the transparent substrate 400, the lower surface of the first p-type semiconductor layer 411 is roughened. The roughened lower surface can be formed during the epitaxial process or by a randomly etching method to form a multi-cavity surface. It also can be formed by a lithographical etching to form a regular or an irregular patterned surface. The first p-type semiconductor layer 411 includes but is not limited to GaP or GaN. The material of the n-type and the second p-type semiconductor layers 412 and 414 includes III-V group compound semiconductor materials such as AlGaInP, AlGaAs, AlGaInN or other ternary or quaternary III-V group compound semiconductor materials. The active layer 413 including III-V group compound semiconductor materials such as AlGaInP, AlGaInN or other materials matched with the n-type and second p-type semiconductor layers 412 and 414. The second transparent conductive oxide layer 420 is formed on the semiconductor light-emitting stack 410, and it includes but is not limited to indium tin oxide, cadmium tin oxide, zinc oxide, or zinc tin oxide. The first electrode 441 is formed on the top of semiconductor light-emitting stack 410. The second electrode 442 is formed on the exposed surface of the first p-type semiconductor layer 411 and extended through the tunnel 450 to the ohmic contact layer 443, and electrically contact with it. The optical field tuning layer 430 includes a first layer 431 and a second layer 432 which covers the exposed surface of the first p-type semiconductor layer 411, the sidewalls of the first p-type semiconductor layer 411, the second p-type semiconductor layer 414, the active layer 413, the n-type semiconductor layer 412, and the second transparent conductive oxide layer 421, and the top surface of the second transparent conductive oxide layer 421. The material of the first layer 431 includes but is not limited to conductive metal oxide or insulating material. The insulating material of the first layer 431 includes but is not limited to SiO₂, SiNₓ, SiON, ZrO₂, Ta₂O₅, Al₂O₃, or TiO₂. The material of the second layer 432 includes but is not limited to conductive metal oxide or insulating material. The insulating material of the second layer 432 includes but is not limited to SiO₂, SiNₓ, SiON, ZrO₂, Ta₂O₅, Al₂O₃, or TiO₂. The conductive metal oxide of the first layer 431 and the second layer 432 includes but is not limited to indium tin oxide, cadmium tin oxide, zinc oxide, or zinc tin oxide. The materials of the first layer 431 and the second layer 432 can also be a multilayer structure composed of different materials such as SiO₂/SiNₓ, SiO₂/TiO₂, SiON/SiNₓ or metal oxide/SiNx.

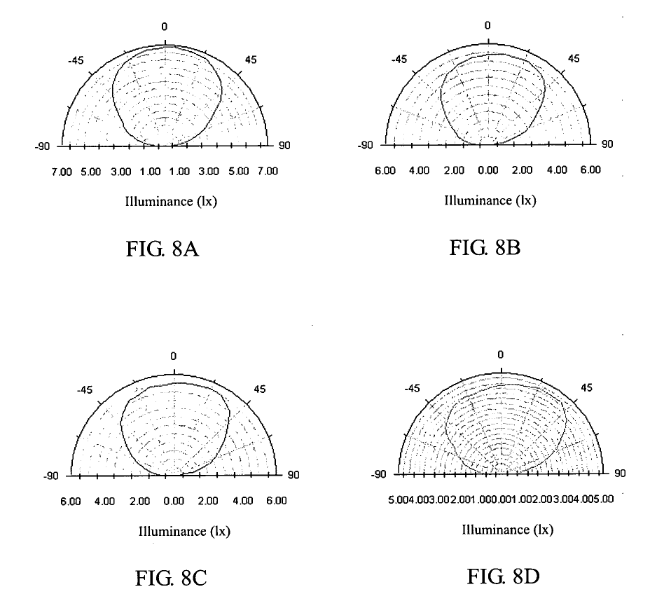

In the embodiment, the material of the semiconductor light-emitting stack 410 is AlGaInP. The material of first layer 431 is SiO₂, the refraction index n₁ is 1.46, and the thickness is 105 nm. The material of the second layer 432 is SiNₓ, the refraction index n₂ is 1.9, and the thickness is 80 nm. Referring to FIGS. 8A-8D, FIG. 8A illustrates the optical field distribution of a conventional light-emitting device without the optical field tuning layer 430. At 50% illuminance (1×) of the optical field distribution, the beam angle of the conventional light-emitting device is 120.5°. FIGS. 8B-8D illustrate the optical field distributions of the light emitting device 4 with one pair, three pairs, and five pairs of the first and second layers 431 and 432 respectively. At 50% illuminance (1×) of the optical field distribution, each beam angles of the light emitting device 4 with one pair, three pairs, and five pairs is 122.9°, 126.6°, and 138.50°. The optical field distribution of the light-emitting device can be varied by tuning the optical field tuning layer 430. The more pairs of the first layer 431 and the second layer 432 the light-emitting device has, the larger beam angle of the optical field distribution is.

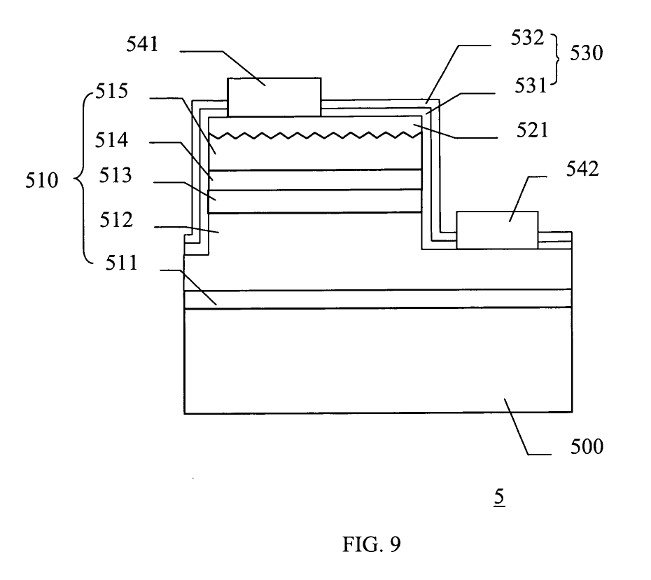

Referring to FIG. 9, the schematic cross-sectional view shows a light-emitting device 5 in accordance with a fifth embodiment of the present invention. The light-emitting device 5 includes a transparent substrate 500, a semiconductor light-emitting stack 510, a first transparent conductive oxide layer 521, an optical field tuning layer 530, and first and second electrodes 541 and 542. In the embodiment, the material of the transparent substrate 500 includes but is not limited to glass, sapphire, SiC, or GaN. The semiconductor light-emitting stack 510 is formed on the transparent substrate 500, including a buffer layer 511, an n-type semiconductor layer 512, a first p-type semiconductor layer 514, a second p-type semiconductor layer 515, and an active layer 513 interposed between the n-type semiconductor layer 512 and the first p-type semiconductor layer 514. The n-type and the first p-type semiconductor layers 512 and 514 act as cladding layers of the LED. The second p-type semiconductor layer 515 is formed on the first p-type semiconductor layer 514 and includes a roughened top surface. The roughened top surface can be formed during the epitaxial process or by a randomly etching method to form a multi-cavity surface. It also can be formed by a lithographical etching to form a regular or an irregular patterned surface. In the embodiment, the semiconductor light-emitting stack 510 is etched partially from the second p-type semiconductor layer 515, first p-type semiconductor layer 514, the active layer 513, to the n-type semiconductor layer 512 to expose partial surface of the n-type semiconductor layer 512. The buffer layer 511 includes but is not limited to GaN, AlN, AlGaN, or GaN. The material of the n-type and the first p-type semiconductor layers 512 and 514 includes but is not limited to AlGaInN or other ternary or quaternary III-V group compound semiconductor materials. The active layer 513 includes but is not limited to AlGaInN or other materials matched with the n-type and the first p-type semiconductor layers 512 and 514. The second p-type semiconductor layer 515 includes but is not limited to GaN or InGaN. The transparent conductive oxide layer 521 is formed on the semiconductor light-emitting stack 510, and it includes but is not limited to indium tin oxide, cadmium tin oxide, zinc oxide, or zinc tin oxide. The first electrode 541 is formed on the top of semiconductor light-emitting stack 510. The second electrode 542 is formed on the exposed surface of the n-type semiconductor layer 512. The optical field tuning layer 530 includes a first layer 531 and a second layer 532 which covers the exposed surface of the n-type semiconductor layer 512, and the sidewalls of the n-type semiconductor layer 512, the active layer 513, the first p-type semiconductor layer 514, the second p-type semiconductor layer 515, and the transparent conductive oxide layer 521, and the top surface of the transparent conductive oxide layer 521.

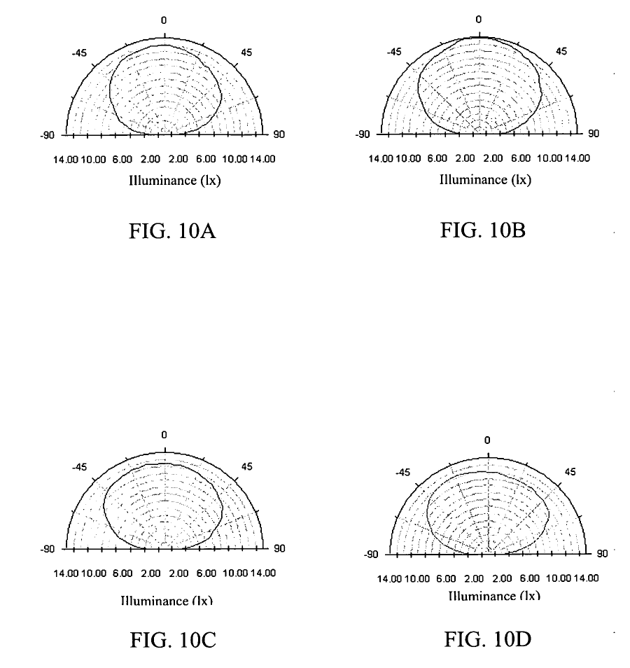

In the embodiment, the material of first layer 531 is SiO₂, the refraction index n₁ is 1.46, and the thickness is 80 nm. The material of the second layer 532 is SiNx, the refraction index n₂ is 1.9, and the thickness is 69 nm. Referring to FIGS. 10A-10E, they illustrate the optical field distributions of a conventional light-emitting device and the light emitting devices of the present invention at 20 mA operating current. FIG. 10A illustrates the optical field distribution of a conventional light-emitting device without the optical field tuning layer 530. At 50% illuminance (1×) of the optical field distribution, the beam angle of the conventional light-emitting device is 146.0°. FIGS. 6B-6E illustrate the optical field distributions of the light emitting device 5 with one pair, three pairs, and five pairs of the first and second layers 531 and 532 respectively. At 50% illuminance (1×) of the optical field distribution, each beam angle of the light emitting device 5 with one pair, three pairs, and five pairs is 149.0°, 153.5°, and 158.4°. The optical field distribution of the light-emitting device 5 can be varied by tuning the optical field tuning layer 530. The more pairs of the first layer 531 and the second layer 532 the light-emitting device has, the larger beam angle of the optical field distribution is.

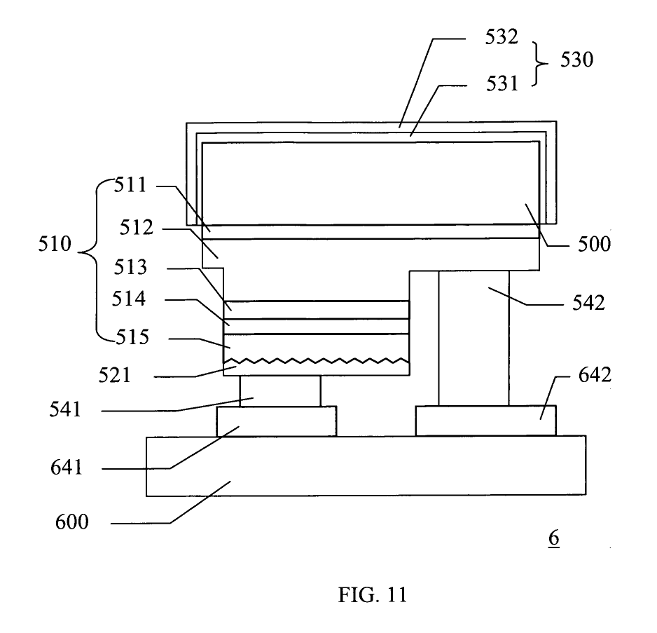

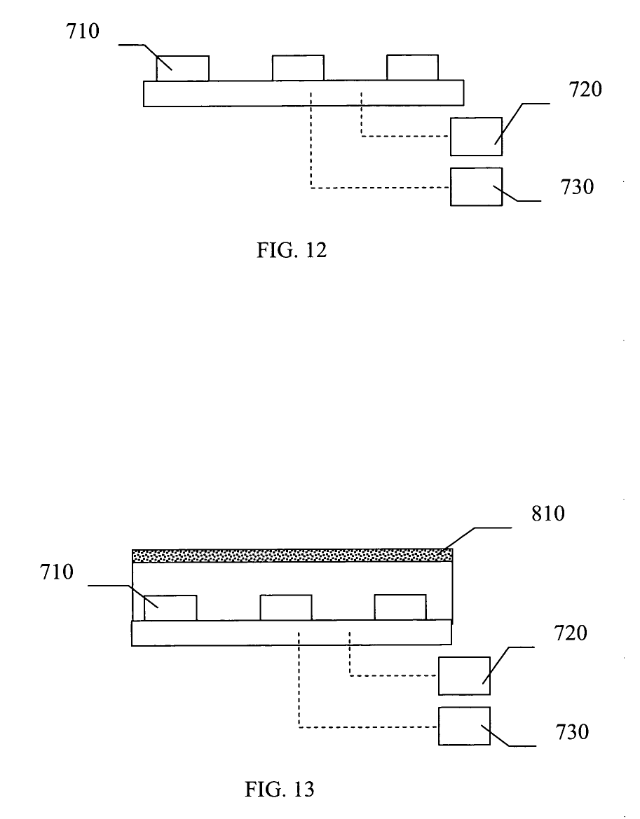

Referring to FIG. 11, the schematic cross-sectional view shows a light-emitting device 6 in accordance with a sixth embodiment of the present invention. The light-emitting device 6 is a flip-chip LED including a carrier 600. The first and second electrodes 541 and 542 are in contact with the first and the second contact electrodes 641 and 642 formed on the carrier 600 respectively. The light emitted from the semiconductor light-emitting stack 510 to the transparent substrate 500 is extracted through the sidewalls of the light emitting device 5 and the surfaces of the transparent substrate 500 opposite to the semiconductor light-emitting stack 510. An optical field with a larger beam angle can be determined by disposing the optical field tuning layer 530 on the transparent substrate 500 to decrease the light extraction of the surface of the transparent substrate 500 opposite to the semiconductor light-emitting stack 510. The first layer 531 is close to the transparent substrate 500, and the refraction index of the first layer 531 is smaller than the refraction index of the second layer 532.

In other embodiment, the semiconductor light-emitting stack 510 includes a roughened surface on the top surface and/or the interface between the semiconductor light-emitting stack 510 and the transparent substrate 500. The roughened surface can be formed during the epitaxial process or by a randomly etching method. It also can be formed by a lithographical etching method to form a regular or an irregular patterned surface.

Referring to FIG. 12, the schematic cross-sectional view shows a light source apparatus 7 in accordance with a seventh embodiment of the present invention. The light source apparatus 7 includes a light emitting device of above embodiments. The light source apparatus 7 is a lighting apparatus such as streetlamps, vehicle lamps, or indoor lightings. It also can be traffic lights or backlights of a module in a planar display. The light source apparatus 7 includes a light source 710 with the light emitting device of above embodiments, a power supply system 720, and a control element 730 for controlling the power supply system 720.

Referring to FIG. 13, the schematic cross-sectional view shows a backlight module 8 in accordance with an eighth embodiment of the present invention. The backlight module 8 includes the light source apparatus 7 and an optical element 810. The optical element is used to operate the light emitted from the light source apparatus 7 to satisfy the quality of the backlight.

In above embodiments, the optical field tuning layer is formed after the epitaxial process, the better is formed after the electrode. The first layer and the second layer of the optical field tuning layer can be tuned based on the user's needs. For the manufacturing processes of the light emitting device, a standard process can be adopted to form a desired optical field distribution without changing the structure of the light emitting device by just tuning the thickness, material composition, or the layer number of the first layer and the second layer of the optical field tuning layer.

It will be apparent to those skilled in the art that various modifications and variations can be made to the structure of the present invention without departing from the scope or spirit of the invention. In view of this, it is intended that the present invention covers modifications and variations of this invention provided they fall within the scope of the following claims and their equivalents.

What is claimed is:

1. A light-emitting device comprising:
a semiconductor light-emitting stack, comprising at least one light extraction surface;
an optical field tuning layer formed directly on the light extraction surface, wherein the optical field tuning layer comprises at least a first layer and a second layer wherein the first layer is closer to the semiconductor light-emitting stack than the second layer and the refraction index of the first layer is smaller than the refraction index of the second layer; and
an electrode formed on the semiconductor light-emitting stack wherein the electrode is in contact with at least one of the light extraction surface and the optical field tuning layer.

2. A light-emitting device according to claim 1, wherein the optical field tuning layer comprises a plurality pairs of the first layer and the second layer.

3. A light-emitting device according to claim 1, wherein either of the first layer and the second layer is composed of the same materials with various proportions, and the refraction index is increased gradually from the first layer to the second layer.

4. A light-emitting device according to claim 1, wherein the semiconductor light-emitting stack comprising an n-type semiconductor layer, a p-type semiconductor layer, and an active layer interposed therebetween.

5. A light-emitting device according to claim 1, further comprising a first transparent conductive oxide layer formed between the semiconductor light-emitting stack and the optical field tuning layer.

6. A light-emitting device according to claim 1, wherein at least one of the first layer and the second layer comprising insulating material or conductive material.

7. A light-emitting device according to claim 6, wherein the insulating material comprising at least one material selected from the group consisting of SiO₂, SiNₓ, SiON, ZrO₂, Ta₂O₅, Al₂O₃, and TiO₂, and the conductive material comprising at least one material selected from the group consisting of indium tin oxide, cadmium tin oxide, zinc oxide, and zinc tin oxide.

8. A light-emitting device according to claim 1, wherein the electrode is in contact with at least one of the first layer and the second layer.

9. A light-emitting device according to claim 1, wherein the semiconductor light-emitting stack comprising a roughened surface.

10. A light-emitting device according to claim 9, wherein the roughened surface is the light extraction surface.

11. A light-emitting device according to claim 9, wherein the roughened surface comprising a patterned surface or a multi-cavity surface.

12. A light-emitting device according to claim 1, further comprising a substrate disposed on the semiconductor light-emitting stack.

13. A light-emitting device according to claim 12, further comprising an interface formed between the semiconductor light-emitting stack and the substrate, wherein the interface is a roughened surface.

14. A light-emitting device according to claim 12, further comprising a first bonding interface formed between the semiconductor light-emitting stack and the substrate.

15. A light-emitting device according to claim 14, further comprising an adhesive layer formed between the semiconductor light-emitting stack and the substrate, wherein the first bonding interface is formed between the adhesive layer and the semiconductor light-emitting stack, and a second bonding interface is formed between the adhesive layer and the substrate.

16. A light-emitting device according to claim 15, wherein the adhesive layer is selected from the group consisting of an insulating adhesive layer and a conductive adhesive layer.

17. A light-emitting device according to claim 16, wherein the insulating adhesive layer comprising at least one material selected from the group consisting of spin on glass (SOG), silicone, polyimide (PI), benzocyclobutene (BCB), perfluorocyclobutane (PFCB), and epoxy, and the conductive adhesive layer comprising at least one material selected from the group consisting of Ag, Au, Al, In, Sn, AuSn alloy, spontaneous conductive polymer, and polymer doping with metal like Al, Au, Pt, Zn, Ag, Ni, Ge, In, Sn, Ti, Pb, Cu, or Pd.

18. A light-emitting device according to claim 14, wherein the first bonding interface and/or the second bonding interface comprises a roughened surface.

19. A light-emitting device according to claim 5, further comprising an distributed contact layer formed between the first transparent conductive oxide layer and the semiconductor light-emitting stack, wherein the distributed contact layer comprising at least one material selected from the group consisting of metal and semiconductor.

20. A light-emitting device according to claim 1, further comprising an electrode formed on the light-emitting stack, wherein the electrode comprising an bonding electrode and an extension electrode, and the optical field tuning layer is formed on or around the electrode.

21. A light-emitting device according to claim 12, wherein the substrate is a transparent substrate, and is formed between the light-emitting stack and the optical field tuning layer.

22. A light-emitting device according to claim 1, wherein the thickness of the first layer is d=1/4n₁m₁×W_{d}, the thickness of the second layer is d=1/4n₂m₂×W_{d}, and wherein n₁ and n₂ is the refraction index of the first layer and the second layer, m is the odd number greater than zero, and W_{d} is the wavelength of the light emitted from the semiconductor light-emitting stack.

23. A light-emitting device comprising:
a light emitting element comprising:
a substrate; and
a semiconductor light-emitting stack; and
an optical field tuning layer formed on the light emitting element, wherein the optical field tuning layer tuning the optical field distribution of the light emitting element and comprising at least a first layer and a second layer on the first layer wherein the first layer is closer to the light emitting element than the second layer and the refraction index of the first layer is smaller than the refraction index of the second layer.
